(19) United States
(12) Patent Application Publication
(10) Pub. No.: US 2025/0028944 A1
(43) Pub. Date: Jan. 23, 2025

(54) SPIKING MAXPOOLING NEURON

(71) Applicant: STMicroelectronics International N.V., Geneva (CH)

(72) Inventors: Jack Iain Maclean, Edinburgh (GB); Brian Douglas Stewart, Edinburgh (GB)

(21) Appl. No.: 18/355,767

(22) Filed: Jul. 20, 2023

(51) Int. Cl. G06N 3/049; H03H 11/04; H03K 17/687

(52) U.S. Cl. CPC G06N 3/049; H03H 11/04; H03K 17/6872

(57) ABSTRACT

According to an embodiment, a max-pooling neuron with first and second integrator circuits, a comparator circuit, a Schmitt trigger circuit, and a pair of switches is provided. The first and second integrator circuits, respectively filter a first and a second input train from a first and a second neuron of a previous layer to generate a corresponding first and second filtered input train. The comparator circuit amplifies a difference between the first and second filtered input trains and generates an amplified differential signal. The Schmitt trigger circuit generates a binary output signal based on the amplified differential signal. The pair of switches have a common first terminal coupled to an output node of the max-pooling neuron and a common control terminal coupled to the output terminal of the Schmitt trigger circuit. The other terminals of the pair of switches are coupled to respective input trains.

### TECHNICAL FIELD

The present disclosure generally relates to neural networks and, in particular embodiments, to a max-pooling neuron of a spiking neural network.

### BACKGROUND

A spiking neural network (SNN) is an artificial neural network that more closely mimics natural neural networks. In addition to neuronal and synaptic states, SNNs incorporate the concept of time into their operating model. The idea is that neurons in the SNN do not transmit information at each propagation cycle (as it happens with typical multi-layer perceptron networks) but rather transmit information only when a membrane potential (an intrinsic quality of the neuron related to its membrane electrical charge) reaches a specific value, called the threshold. When the membrane potential reaches the threshold, the neuron fires and generates a signal that travels to other neurons, increasing or decreasing their potentials in response to this signal.

### SUMMARY

Technical advantages are generally achieved by embodiments of this disclosure which describe a max-pooling neuron of a spiking neural network.

A first aspect relates to a max-pooling neuron. The max-pooling neuron includes a first integrator circuit, a second integrator circuit, a comparator circuit, a Schmitt trigger circuit, and a pair of switches. The first integrator circuit is configured to filter a first input train from a first neuron of a previous layer and generate a first filtered input train. The second integrator circuit is configured to filter a second input train from a second neuron of the previous layer and generate a second filtered input train. The comparator circuit is configured to amplify a difference between the first filtered input train and the second filtered input train and generate an amplified differential signal. The Schmitt trigger circuit is configured to generate a binary output signal at an output terminal of the Schmitt trigger circuit based on the amplified differential signal. The pair of switches include a first switch and a second switch. The pair of switches have a common first terminal coupled to an output node of the max-pooling neuron and a common control terminal coupled to the output terminal of the Schmitt trigger circuit. A second terminal of the first switch is coupled to the first input train. A second terminal of the second switch is coupled to the second input train.

A second aspect relates to a max-pooling layer with a max-pooling neuron. The max-pooling neuron includes a first integrator circuit, a second integrator circuit, a comparator circuit, a Schmitt trigger circuit, and a pair of switches. The first integrator circuit is configured to filter a first input train from a first neuron of a previous layer and generate a first filtered input train. The second integrator circuit is configured to filter a second input train from a second neuron of the previous layer and generate a second filtered input train. The comparator circuit is configured to amplify a difference between the first filtered input train and the second filtered input train and generate an amplified differential signal. The Schmitt trigger circuit is configured to generate a binary output signal at an output terminal of the Schmitt trigger circuit based on the amplified differential signal. The pair of switches include a first switch and a second switch. The pair of switches have a common first terminal coupled to an output node of the max-pooling neuron and a common control terminal coupled to the output terminal of the Schmitt trigger circuit. A second terminal of the first switch is coupled to the first input train. A second terminal of the second switch is coupled to the second input train.

A third aspect relates to a neural network. The neural network includes a first layer and a max-pooling layer. The first layer includes a first neuron and a second neuron. The first neuron is configured to provide a first input train. The second neuron is configured to provide a second input train. The max-pooling layer includes a max-pooling neuron. The max-pooling neuron includes a first integrator circuit, a second integrator circuit, a comparator circuit, a Schmitt trigger circuit, and a pair of switches. The first integrator circuit is configured to filter a first input train from a first neuron of a previous layer and generate a first filtered input train. The second integrator circuit is configured to filter a second input train from a second neuron of the previous layer and generate a second filtered input train. The comparator circuit is configured to amplify a difference between the first filtered input train and the second filtered input train and generate an amplified differential signal. The Schmitt trigger circuit is configured to generate a binary output signal at an output terminal of the Schmitt trigger circuit based on the amplified differential signal. The pair of switches include a first switch and a second switch. The pair of switches have a common first terminal coupled to an output node of the max-pooling neuron and a common control terminal coupled to the output terminal of the Schmitt trigger circuit. A second terminal of the first switch is coupled to the first input train. A second terminal of the second switch is coupled to the second input train.

Embodiments can be implemented in hardware, software, or any combination thereof.

### BRIEF DESCRIPTION OF THE DRAWINGS

For a more complete understanding of the present disclosure and the advantages thereof, reference is now made to the following descriptions taken in conjunction with the accompanying drawings, in which:

FIG. 1 is a block diagram of an artificial neuron in a traditional artificial neural network;

FIG. 2 is a block diagram of a Leaky Integrate-and-Fire (LIF) neuron in an embodiment Spiking Neural Network (SNN;

FIG. 3 is a timing diagram of the membrane potential corresponding to the LIF neuron;

FIG. 4 is a block diagram of an embodiment Single-Photon Avalanche Diode (SPAD) system using a spiking neural network implemented in a vehicle;

FIG. 5 is a block diagram of an embodiment spiking neural network;

FIG. 6 is a block diagram of an embodiment max-pooling neuron;

FIG. 7 is a schematic of an embodiment max-pooling neuron;

FIG. 8 is a schematic of an embodiment max-pooling neuron;

FIG. 9 shows signals of an embodiment operation sequence of a max-pooling neuron;

FIG. 10 shows signals of an embodiment operation sequence of a max-pooling

neuron;

FIG. 11 shows signals of an embodiment operation sequence of a max-pooling neuron; and

FIG. 12 shows signals of an embodiment operation sequence of a max-pooling neuron.

### DETAILED DESCRIPTION OF ILLUSTRATIVE EMBODIMENTS

This disclosure provides many applicable inventive concepts that can be embodied in a wide variety of specific contexts. The particular embodiments are merely illustrative of specific configurations and do not limit the scope of the claimed embodiments. Features from different embodiments may be combined to form further embodiments unless noted otherwise.

Variations or modifications described in one of the embodiments may also apply to others. Further, various changes, substitutions, and alterations can be made herein without departing from the spirit and scope of this disclosure as defined by the appended claims.

While the inventive aspects are described primarily in the context of a max-pooling neuron in a max-pooling layer of a spiking neural network, it should also be appreciated that these inventive aspects may also apply to any neuron of a neural network layer that can benefit from the embodiments disclosed herein. Further, besides applying to remote sensing devices and image sensing applications, these inventive aspects can benefit other devices and applications that utilize a low-power learning system, such as autonomous vehicles, drones, and robots. Moreover, aspects of this disclosure may similarly apply to commercial and industrial applications.

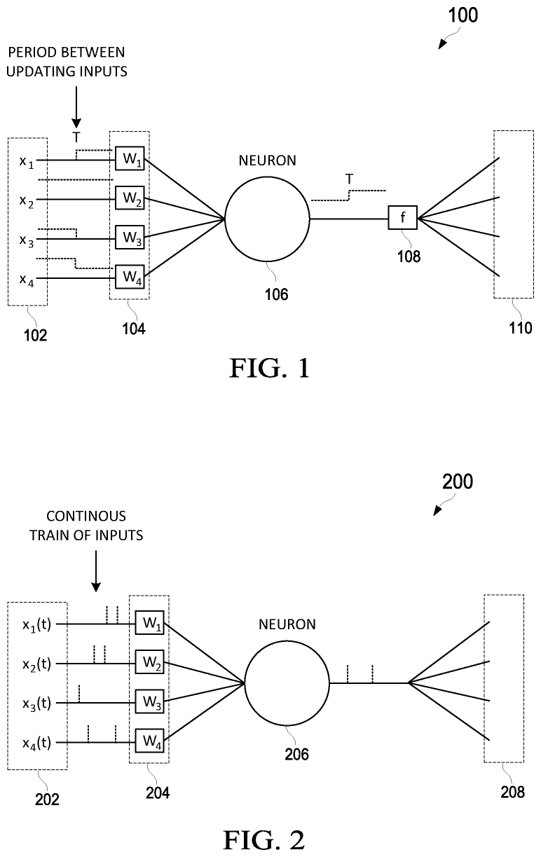

FIG. 1 illustrates a block diagram of an artificial neuron 106 in a traditional artificial neural network 100. In the traditional artificial neural network 100, the artificial neuron 106 operates within a fixed update period (T) and with constant activation levels. The inputs 102 are biased using bias terms (i.e., weights) 104 and summed together by the artificial neuron 106. The output of the artificial neuron 106 is then passed through an activation function (f) 108, typically a Rectified Linear Unit (ReLU), and provided, for example, to the next artificial neuron of the traditional artificial neural network 100.

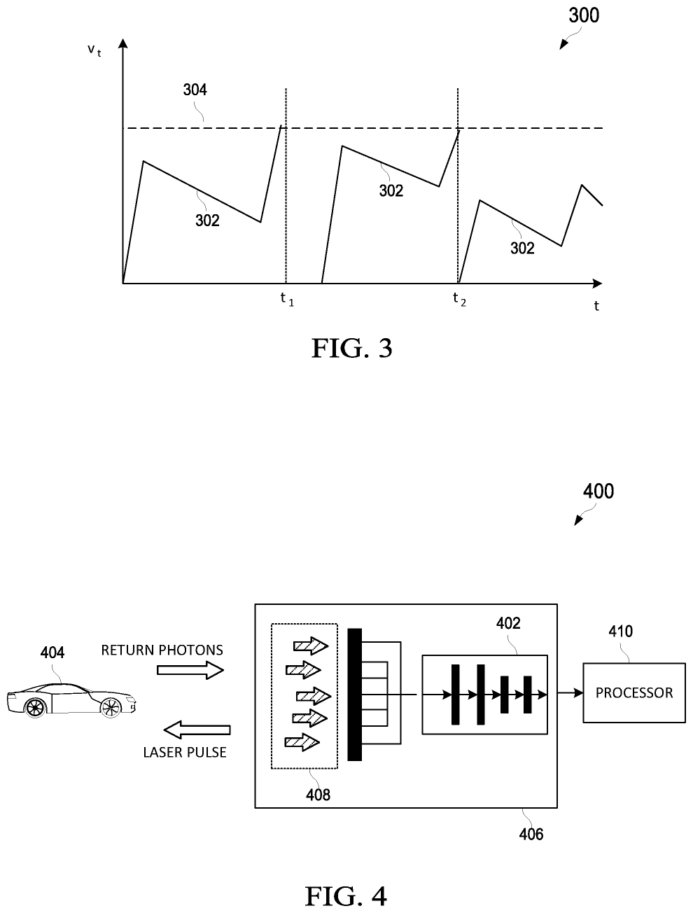

FIG. 2 illustrates a block diagram of a Leaky Integrate-and-Fire (LIF) neuron 206 in an embodiment Spiking Neural Network (SNN) 200. FIG. 3 illustrates a timing diagram 300 of the membrane potential 302 corresponding to the LIF neuron 206. It is noted that each LIF neuron 206 maintains its respective membrane potential.

In contrast with the traditional artificial neural network 100, which operates synchronously, spiking neural network 200 operates asynchronously. As the spiking neural network 200 incorporates time in its operating model, a continuous train of inputs 202 is continuously biased using bias terms 204 and provided to LIF neuron 206. In response to the arrival of input spikes in the continuous train of inputs 202 at the LIF neuron 206, the potential (vₜ) of the membrane potential 302 increases over time. In contrast, an absence of input spikes in the continuous train of inputs 202 decreases the potential (vₜ) of the membrane potential 302. When the membrane potential 302 reaches the fire threshold 304, an output spike is produced in the continuous train of outputs 306, and the membrane potential 302 is reset, represented as time t₁ and t₂ in the timing diagram 300.

Using spikes allows for better time, frequency, and phase information integration. Other appealing qualities spiking neural networks offer are greater data sparsity and lower power consumption than traditional synchronous networks.

While the advantages of the spiking neural network 200 are well-known, the main problem preventing their widespread use has been the need for a developed training method, limiting their size to a few layers. One way to circumvent this has been to convert the traditionally trained artificial neural network into a spiking equivalent. However, the process for conversion puts limitations on the layer and activation types that can be used in the modified network. As the activations of the original artificial neural network are approximated using spiking equivalents, the overall accuracy deteriorates for every layer in the modified network.

FIG. 4 illustrates a block diagram of an embodiment Single-Photon Avalanche Diode (SPAD) system 400 using a spiking neural network 402 implemented in, for example, a vehicle 404, which may (or may not) be arranged as shown. SPAD system 400 may include additional components not depicted.

As training techniques and resources for deep neural networks have improved, so has the use of the spiking neural network 402. These neuromorphic networks are predisposed to take advantage of the event-based nature of, for example, the Single-Photon Avalanche Diode (SPAD) sensor 406.

Vehicle 404 is outfitted with a SPAD sensor 406, which is a remote sensing device, such as, for example, a Light Detection and Ranging (LIDAR) sensor. In embodiments, SPAD sensor 406 provides a laser pulse to a transmitting device within vehicle 404 and receives the reflected photons 408 from the objects surrounding the vehicle 404. The reflected photons 408 are passed through the spiking neural network 402 and classified, analyzed, and processed by processor 410.

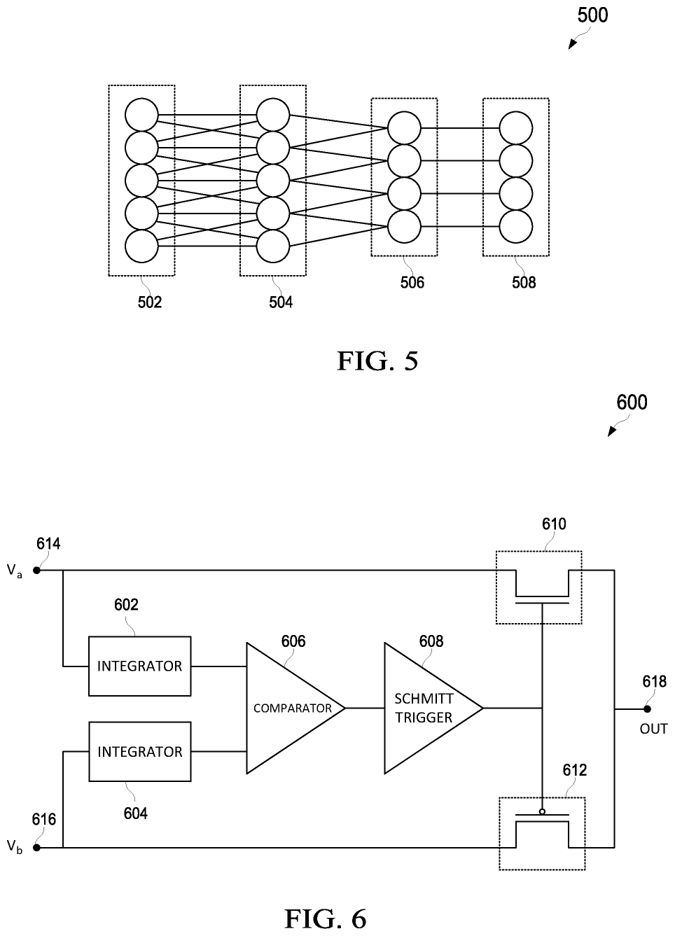

FIG. 5 illustrates a block diagram of an embodiment spiking neural network 500, which may be implemented in the spiking neural network 402 of SPAD sensor 406. Spiking neural network 500 includes an input layer 502, a convolutional layer 504, a max-pooling layer 506, and an output layer 508, which may (or may not) be arranged as shown. Although five neurons are shown in input layer 502 and convolutional layer 504, and four are shown in the max-pooling layer 506 and output layer 508, it should be understood that greater or fewer neurons are similarly contemplated in embodiments. The number of neurons is generally set based on the number of features in the input dataset. Further, spiking neural network 500 may include additional layers between the input layer 502 and the output layer 508.

Input layer 502 includes artificial input neurons. Input layer 502 provides the initial data for further processing by, for example, the convolutional layer 504 and max-pooling layer 506. Input layer 502 is the beginning of the workflow for the spiking neural network 500 and, typically, does not perform any transformation on the data. Although five artificial input neurons are shown in input layer 502, greater or less are contemplated and generally are set based on the number of features in the input dataset.

Convolutional layer 504 is typically used to analyze visual imagery, such as data collected from SPAD sensor 406. Convolution layer 504 uses a mathematical operation called convolution instead of general matrix multiplication. Effectively, convolution layer 504 allows the three-dimensional frame or image to be used as input data for the neural network. Although five artificial input neurons are shown in input layer 502, greater or less are contemplated and generally are set based on the number of features in the input dataset. It should be understood that using a convolutional layer 504 in the spiking neural network 402 is non-limiting.

In spiking neural networks, the maximum activation in the field of view is the input neuron producing spikes at the highest frequency. The neurons in the max-pooling layer 506 find the maximum activation within the field of view, which is propagated to the next layer. The max-pooling operation consists of extracting windows from input feature maps and outputting the maximum value of each channel. When max-pooling layer 506 is added to the neural network model, the dimensionality of images is reduced by decreasing the number of pixels in the output from the previous layer.

Conventionally, spiking neural networks have had limited implementations of the max-pooling layer 506. Existing solutions typically apply some function to each neuron separately and then evaluate which neurons' spike train will be propagated to the next layer using external electronics.

A first existing solution is a time-to-first spike, which operates by simply passing on the spike train of the input neuron which happened to spike first. This approach only works under the assumption that the neuron that spikes first is also the neuron that will be spiking at the higher rate; however, this assumption does not reflect reality as not all the neurons will have a membrane potential of zero at the start of any integration period.

A second existing solution uses a pooling gate to connect an input neuron to the output neuron based on its functions, which define the criteria for the maximally firing neuron. While this solution can circumvent some issues with time-to-first spike, it is difficult to dynamically switch due to the decay of the additive second term with time. The only way to ensure that the dynamic frequency switching is represented is to introduce a fixed integration period that resets at the end, allowing any change in input frequencies to be accounted for. This solution is limited to being implemented in software.

A third solution uses spiking approximations, such as in Max Join-Op (MJOP) or Associative Max (AVAM). MJOP is a method specific to the architecture of the Loihi neuromorphic hardware platform. It first passes the incoming spike trains through a low-pass filter which charges the membrane potential of their respective compartments. The max is calculated in a binary tree for multiple inputs. The solution MJOP provides is limited due to the specific hardware platform it requires for operation.

AVAM is a more generic hardware model built on Neural Engineering Framework (NEF) principles. In AVAM a max function is implemented by first filtering the incoming spike train and passing that signal into the max-pooling neuron. The max-pooling process is performed by splitting the max function into two terms. The first term is achieved by multiplying two inputs by, for example, 0.5 and connecting them to the output node P. The second term is implemented by passing the inputs to an ensemble containing the neurons A & B, with input 1 having a weight of 0.5 and input 2 a weight of −0.5. The inputs are added together, and the absolute term is achieved via the tuning curves of the A & B neurons, where A spikes if the result of the addition is negative and B spikes if it is positive. This output is then multiplied by r/Φ to connect it to the output node, where r is the radius of the range of values that can be represented and Φ represents the maximum firing rate. While the system operates well on firing rates, it still incurs a significant error recreating the input maximally firing neurons spike train. This error is incurred due to the slew rate introduced by the filtering process, which means the filtered currents charge the membrane potential of the max-pooling neurons at a lower rate initially.

Disadvantageously, these solutions typically do not allow for dynamic switching between neurons if the spike rate of the input neurons changes due to a change in external stimulus. Further, the existing solutions generally require external synchronous hardware to sample and clock the electronics required for implementations, reducing the benefit of the asynchronous nature of the spiking neural network.

FIG. 6 illustrates a block diagram of an embodiment max-pooling neuron 600, which may be implemented as a neuron in the max-pooling layer 506 of the spiking neural network 500. Max-pooling neuron 600 includes integrator circuits 602, 604, comparator circuit 606, optionally a Schmitt trigger circuit 608, and transistors 610, 612, which may (or may not) be arranged as shown. Max-pooling neuron 600 may include additional components not depicted.

The input spiking signal 614 received at the first integrator circuit 602 is the output (Vₐ) from a first neuron in the previous layer (e.g., convolutional layer 504). In contrast, the input spiking signal 616 received at the second integrator circuit 604 is the output (V_{b}) from a second neuron in the previous layer. At a high-level, max-pooling neuron 600 operates as a switch connecting the maximally firing input neuron (i.e., first or second neuron) from a previous layer to the output of the max-pooling neuron and, for example, to a next layer.

One of the major disadvantageous of existing modified spiking neural networks is that they poorly respond to a change in the input frequency. For example, in previous solutions, when the second neuron providing the input spiking signal 616 begins to fire at a higher rate than the first neuron providing the input spiking signal 614, the previous max-pooling solutions are slow to respond or not able to respond (i.e., in the case of an exponential decay method solution). Embodiments of this disclosure provide a max-pooling neuron 600, which can quickly respond to changes in the input frequency.

The integrator circuits 602, 604 perform a mathematical integration on the input spiking signals 614, 616. First integrator circuit 602 provides a first voltage based on input spiking signal 614, and second integrator circuit 604 provides a second voltage based on input spiking signal 616 to the comparator circuit 606. In embodiments, integrator circuits 602, 604 are low-pass filters, which can be implemented using, for example, an operational amplifier (op-amp) and passive components such as resistors and capacitors. In embodiments, integrator circuits 602, 604 form a filter stage of max-pooling neuron 600. In embodiments, integrator circuits 602, 604 average out the input spiking signals 614, 616, such that the output voltage (at the output of the integrator circuits 602, 604) is proportional to the firing rate.

Comparator circuit 606 compares the first and second voltages (i.e., proportional voltage levels of input spiking signals 614, 616) received from integrator circuits 602, 604. Comparator circuit 606 determines which neuron is firing at a higher rate based on the magnitude of the first and second voltages. Comparator circuit 606 produces an amplified signal based on the comparison result to Schmitt trigger circuit 608. In embodiments, the amplified signal is a digital binary signal, indicating a high or low state based on the voltage comparison. In other embodiments, the amplified signal is an analog value. Comparator circuit 606 can be implemented using, for example, an op-amp and resistors. In embodiments, comparator circuit 606 forms a voltage comparison stage of max-pooling neuron 600.

Schmitt trigger circuit 608 is used to stabilize (i.e., improve stability) the output voltage of the comparator circuit 606 and prevent frequent switching due to small oscillations by introducing hysteresis on the output of the comparator circuit 606.

In embodiments, Schmitt trigger circuit 608 converts the analog amplified signal into a binary output signal that switches between two voltage levels based on specified thresholds. In embodiments, Schmitt trigger circuit 608 includes upper and lower threshold voltages. When the input voltage rises above the upper threshold voltage, the output of the Schmitt trigger circuit 608 switches to a high state and remains in this high state until the input voltage drops below the lower threshold voltage; at this point, the output switches to a low state. This hysteresis between the upper and lower thresholds helps eliminate noise-induced fluctuations and provides a more stable and well-defined output.

Advantageously, the Schmitt trigger circuit 608 provides a stable output from the comparator circuit 606. Thus, it should be understood that implementing the Schmitt trigger circuit 608 in the max-pooling neuron 600 is non-limiting. In embodiments, the max-pooling neuron 600 may not include the Schmitt trigger circuit 608. In other embodiments, other circuits or methodologies may be implemented in max-pooling neuron 600 to improve the stability at the output of the comparator circuit 606.

Transistors 610, 612 are arranged as a complementary metal-oxide-semiconductor (CMOS) formed by complementary and symmetrical pairs of p-type (i.e., second transistor 612) and n-type (i.e., first transistor 610) metal-oxide-semiconductor field-effect transistors (MOSFETs). The control (i.e., gate) terminal of the p-type MOSFET (i.e., second transistor 612) is coupled to the control terminal of the n-type (i.e., first transistor 610) MOSFET and coupled to the output terminal of the Schmitt trigger circuit 608. The drain (e.g., output) terminal of the p-type MOSFET (i.e., second transistor 612) is coupled to the drain terminal of the n-type (i.e., first transistor 610) MOSFET and coupled to the output node 618 of the max-pooling neuron 600. The source (e.g., input) terminal of the n-type MOSFET (i.e., first transistor 610) is coupled to the first neuron and receives the input spiking signal 614. The source terminal of the p-type MOSFET (i.e., second transistor 612) is coupled to the second neuron and receives the input spiking signal 616.

The composition of the p-type transistor (i.e., second transistor 612) creates low resistance between its source and drain contacts when a low gate voltage from the Schmitt trigger circuit 608 is applied and high resistance when a high gate voltage from the Schmitt trigger circuit 608 is applied. On the other hand, the composition of the n-type transistor (i.e., first transistor 610) creates high resistance between the source and drain when a low gate voltage from the Schmitt trigger circuit 608 is applied and low resistance when a high gate voltage from the Schmitt trigger circuit 608 is applied. Thus, the first transistor 610 is configured to activate at a high state at its gate terminal. In contrast, the second transistor 612 is configured to activate at a low state at its gate terminal.

Transistors 610, 612 are used as switches to control which frequency spiking signal is passed to the next layer (e.g., output layer 508) at output node 618. In embodiments, transistors 610, 612 form a switching stage of max-pooling neuron 600.

Transistors 610, 612 effectively couple one of the input spiking signal 614 or the input spiking signal 616 to the output node 618 of the max-pooling neuron 600. At the high state of the output of the Schmitt trigger circuit 608, the first transistor 610 is selected to couple the input spiking signal 614 from the first neuron to the output node 618. At the low state of the output of the Schmitt trigger circuit 608, the second transistor 612 is selected to couple the input spiking signal 616 from the second neuron to the output node 618. The first transistor 610 or the second transistor 612 is always active, so a spiking signal is always propagated to the next layer.

As the system stabilizes from a change in input frequencies, small errors may be present in the output of the max-pooling neuron 600 (i.e., it may miss a spike or two along the continuous train of inputs); however, the impact of such errors on the overall firing rate is considered negligible for most applications.

Previous solutions for implementing a max-pooling layer to a spiking neural network use the spikes in the input signal to charge a capacitor. The resultant charge was then measured after a period to determine the higher firing rate. Further, previous solutions introduced an integration period before the higher frequency signal could be passed onto the next level. Disadvantageously, these solutions necessitated external clocking and additional electronics for the measurements, resulting in higher power consumption, complexity, and increased chip space. The integration period increased neural network processing time and introduced information loss due to the paralysis of the neural network while integrating the signal. Moreover, as the magnitude of updates to the stored value decreased with time, dynamic switching could not occur within a reasonable time, meaning that even if another neuron later began firing at a higher frequency rate, it would not be chosen as the highest frequency without a system reset.

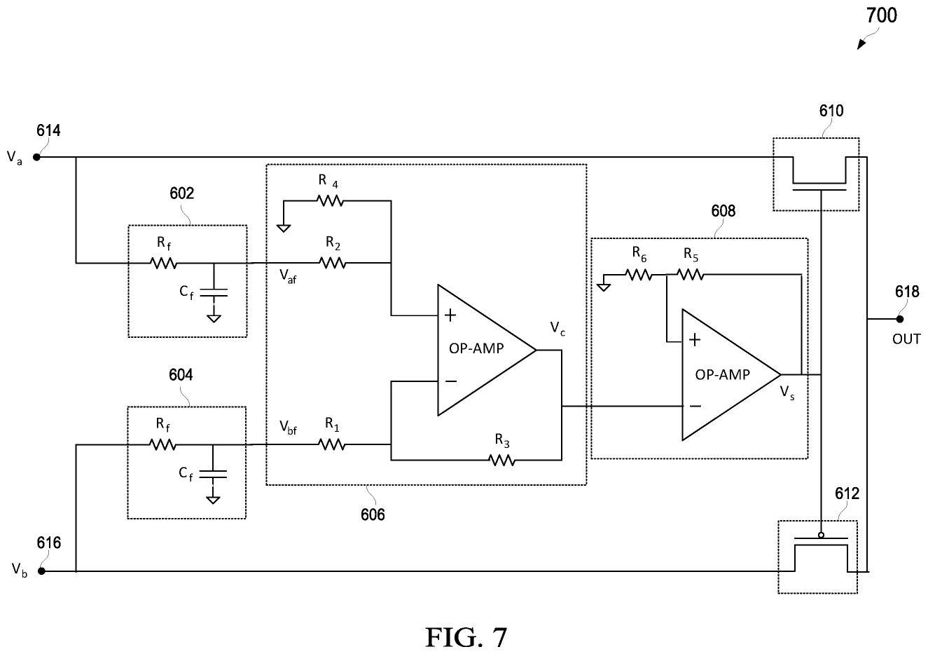

FIG. 7 illustrates a schematic of an embodiment max-pooling neuron 700, which may be implemented as max-pooling neuron 600. Max-pooling neuron 700 is an analog circuit with passive analog components that do not rely on external electronics or clock signals. Max-pooling neuron 700 includes integrator circuits 602, 604, comparator circuit 606, Schmitt trigger circuit 608, and transistors 610, 612, which may (or may not) be arranged as shown. Max-pooling neuron 700 may include additional components not depicted.

The use of passive components reduces design complexity and decreases power consumption. Further, the circuit design allows for dynamic switching of neurons, as there is no integration period or set update period, preventing information loss. Specifically, the neuron dynamic switching can be controlled by the filter time constant (τ_{c}) of the integrator circuits 602, 604, the gain (G) of the comparator circuit 606, and the trigger level (β) of the Schmitt trigger circuit 608.

Integrator circuits 602, 604 are implemented as a low-pass filter circuit in max-pooling neuron 700. In embodiments, the first integrator circuit 602 is formed by the resistor (R_{f}) and capacitor (C_{f}), which is arranged as a shunt capacitor. Likewise, the second integrator circuit 604 is formed by the resistor (R_{f}) and capacitor (C_{f}). By appropriately selecting the values of the resistor (R_{f}) and capacitor (C_{f}) in the integrator circuits 602, 604, the cutoff frequency of the low-pass filter circuit can be set.

In embodiments, the low-pass filter circuit is set with a low cut-off frequency to integrate the incoming spike train. First integrator circuit 602 provides a first voltage (V_{af}) based on input spiking signal 614, and second integrator circuit 604 provides a second voltage (V_{bf}) based on input spiking signal 616 to the comparator circuit 606.

Comparator circuit 606 is implemented as an op-amp with the non-inverting input (+) coupled to the first voltage (V_{af}) and the inverting input (−) coupled to the second voltage first voltage (V_{bf}). The op-amp compares the two filtered spike train currents with a gain applied to increase the output voltage.

In embodiments, comparator circuit 606 includes a first resistor (R₁) arranged between the inverting input (−) and the output of the second integrator circuit 604, a second resistor (R₂) arranged between the non-inverting input (+) and the output of the first integrator circuit 602, a third resistor (R₃) arranged between an output (V_{c}) of the op-amp and the inverting input (−), and a fourth resistor (R₄) arranged between the non-inverting input (+) and a reference ground. By appropriately selecting the resistance values of the first resistor (R₁), second resistor (R₂), third resistor (R₃), and fourth resistor (R₄), the gain of the op-amp can be set.

Schmitt trigger circuit 608 is implemented as an op-amp with an inverting input (−) coupled to the output (V_{c}) of the comparator circuit 606. In embodiments, a fifth resistor (R₅) is coupled between an output of the op-amp (Vₛ) and the non-inverting input (+) of the Schmitt trigger circuit 608 op-amp. A sixth resistor (R₆) is coupled between the reference ground and the non-inverting input (+) of the Schmitt trigger circuit 608 op-amp. By appropriately selecting the resistance values of the fifth resistor (R₅) and sixth resistor (R₆), the trigger level (β) of the Schmitt trigger circuit 608 can be set.

The AVAM max-pooling neuron includes two LIF neurons, six synaptic connections, and two filters. Each AVAM max-pooling neuron requires at least three transistors, though some can require up to twenty-one. At least two transistors, possibly up to twelve, may be required for each synapse of the AVAM max-pooling neuron. Thus, at a minimum, the AVAM max-pooling neuron includes eighteen transistors, six capacitors, four resistors, and a p-n-p-n diode. However, implementing an AVAM max-pooling neuron could be more resource intensive.

In contrast, max-pooling neuron 600 can be implemented using ten transistors, eight resistors, and two capacitors. While max-pooling neuron 600 uses fewer transistors and capacitors, it may require more resistors, which can be costly. However, alternate configurations of max-pooling neuron 600 with fewer resistors are contemplated in other embodiments.

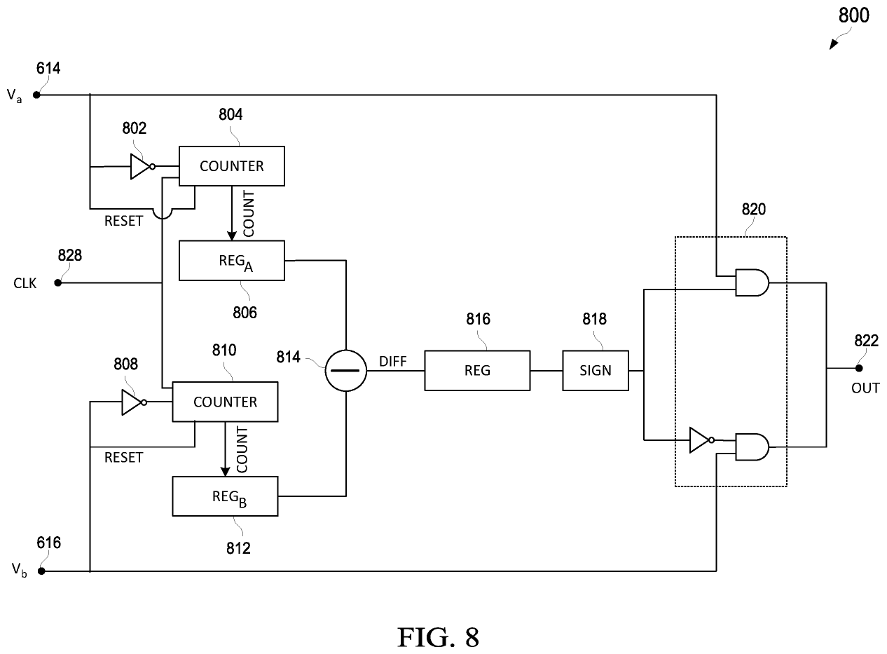

FIG. 8 illustrates a schematic of an embodiment max-pooling neuron 800, which may be implemented as a neuron in the max-pooling layer 506 of the spiking neural network 500. In contrast to max-pooling neuron 700, an analog circuit, max-pooling neuron 800 is implemented as a digital circuit. Max-pooling neuron 800 includes inverters 802, 808, counters 804, 810, registers 806, 812, and 816, a subtraction circuit 814, a sign circuit 818, and a digital circuit 820, which may (or may not) be arranged as shown. max-pooling neuron 800 may include additional components not depicted.

Input spiking signal 614 from a first neuron is inverted by inverter 802 and received at a first counter 804. Input spiking signal 616 from a second neuron is inverted by inverter 808 and received at a second counter 810. Counters 804, 810 continuously count the clocks (CLK) from a clock signal coupled to node 828 between respective spikes of the input spiking signals 614, 616.

In response to a spike occurring in the input spiking signal 614, the value of the first counter 804 is stored in the first register (Reg_{A}) 806. However, if no spike occurs and the number of clocks counted by the first counter 804 is greater than the value presently stored in the first register (Reg_{A}) 806, then the first register (Reg_{A}) 806 is updated with a weighted sum of the number of clocks and the value presently stored in the first register (Reg_{A}) 806. Otherwise, first register (Reg_{A}) 806 is not updated (if no spike occurs and the number of clocks counted by the first counter 804 is less than or equal to the value presently stored in the first register (Reg_{A}) 806).

In embodiments, the spike occurrence can cause the corresponding counter to be reset to, for example, zero. In embodiments, the current value of the corresponding counter is stored before it is reset.

In response to a spike occurring in the input spiking signal 616, the value of the second counter 810 is stored in the second register (Reg_{B}) 812. However, if no spike occurs and the number of clocks counted by the second counter 810 is greater than the value presently stored in the second register (Reg_{B}) 812, then the second register (Reg_{B}) 812 is updated with a weighted sum of the number of clocks and the value presently stored in the second register (Reg_{B}) 812. Otherwise, second register (Reg_{B}) 812 is not updated (if no spike occurs and the number of clocks counted by the second counter 810 is less than or equal to the value presently stored in second register (Reg_{B}) 812.

The subtraction circuit 814 receives the value stored in the first register (Reg_{A}) 806 and subtracts it from the value stored in the second register (Reg_{B}) 812, as a differential signal. The differential signal is stored in the third register 816. A sign circuit 818 receives the differential signal from the third register 816 and provides a high state output if the value stored in the third register 816 is positive; otherwise, the sign circuit 818 provides a low state output (i.e., when the value stored in the third register 816 is negative).

A digital circuit 820 is arranged between the sign circuit 818 and the output node 822 of the max-pooling neuron 800. Digital circuit 820 includes a first AND gate having a first input coupled to the input spiking signal 614 and a second input coupled to the output of the sign circuit 818. Further, the digital circuit 820 includes a second AND gate having a first input coupled to the input spiking signal 616 and a second input coupled to the inverted output of the sign circuit 818 through an inverter gate.

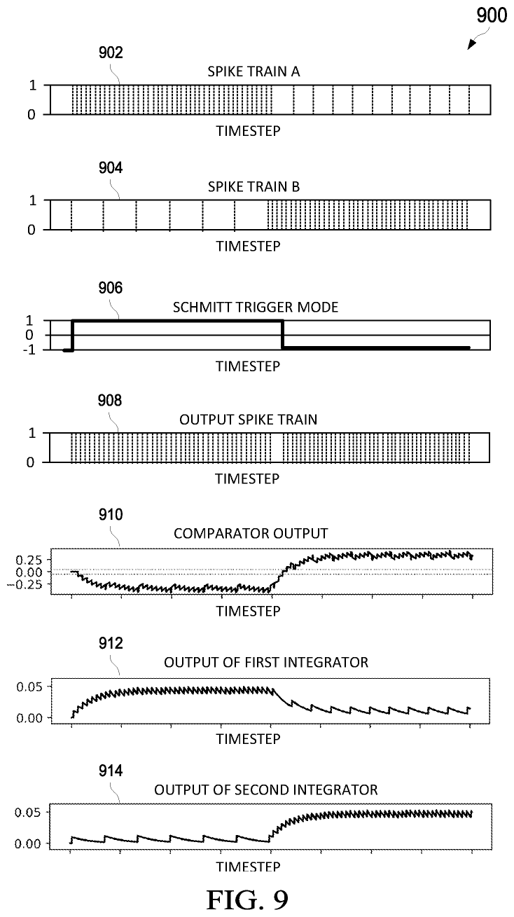

FIG. 9 illustrates signals 900 of an embodiment operation sequence of a max-pooling neuron, as implemented in a max-pooling layer of a spiking neural network. Signals 900 include input spiking signal 902 from a first neuron in a previous layer, input spiking signal 904 from a second neuron in the previous layer, Schmitt trigger mode signal 906, output signal 908, comparator signal 910, first integrator signal 912, and second integrator signal 914.

In embodiments, the input spiking signal 902 corresponds to, for example, the input spiking signal 614. In embodiments, the input spiking signal 904 corresponds to, for example, the input spiking signal 616. In embodiments, the first integrator signal 912 corresponds to the output of, for example, the first integrator circuit 602. In embodiments, the second integrator signal 914 corresponds to the output of, for example, the second integrator circuit 604. In embodiments, the comparator signal 910 corresponds to, for example, the output of the comparator circuit 606. In embodiments, Schmitt trigger mode signal 906 corresponds to the output of the Schmitt trigger circuit 608 and is fed to the transistors 610, 612. In embodiments, the output signal 908 corresponds to the output node 618, which is fed to the next neuron.

Input spiking signal 902 has a higher firing rate than input spiking signal 904 from the start until the halfway point. Input spiking signal 904 has a higher firing rate than input spiking signal 902 from the halfway point until the end. As shown, input spiking signal 902 transitions from a high-frequency (e.g., 436 Hz) to a low-frequency (e.g., 110 Hz) spiking at the halfway point of the timing steps (x-axis). The first integrator signal 912 represents the input spiking signal 902. In contrast, input spiking signal 904 transitions from a low-frequency (e.g., 74 Hz) to a high-frequency (e.g., 475 Hz) spiking at the same halfway point of the timing steps. The second integrator signal 914 represents the input spiking signal 904.

At approximately the halfway point (with an additional delay), the Schmitt trigger mode signal 906 transitions from high (e.g., ‘1’) to low (e.g., ‘−1’) as the comparator signal 910 transitions from a lower voltage to a higher voltage.

The output signal 908 corresponds to the input spiking signal 902 from the first neuron until the halfway point (e.g., at a frequency of 420 Hz). After a slight delay, the output signal 908 corresponds to the input spiking signal 904 from the second neuron (e.g., at a frequency of 440 Hz).

Thus, the spike train of the maximally firing neuron (from the previous layer) is passed on mostly unaffected. An error may occur due to the slew rate of the filtered input, which causes a delay in the change of inputs, corresponding to the voltage drop across the transistors in the hardware implementation. The delay in the switchover can be adjusted by setting the filter time constant (τ_{c}) of the integrator circuits 602, 604, the trigger level (β) of the Schmitt trigger circuit 608, or a combination thereof. However, the reduction of the delay may cause input instability.

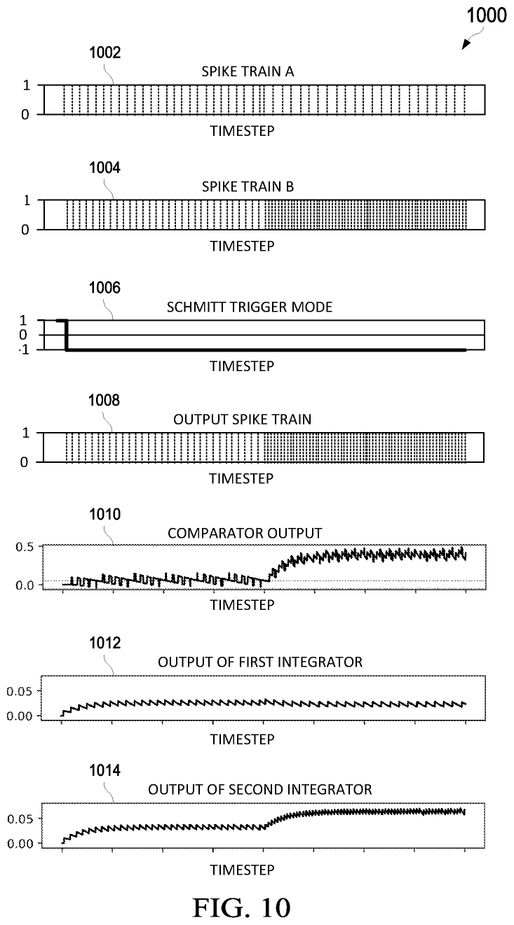

FIG. 10 illustrates signals 1000 of an embodiment operation sequence of a max-pooling neuron, as implemented in a max-pooling layer of a spiking neural network. Signals 1000 include input spiking signal 1002 from a first neuron in a previous layer, input spiking signal 1004 from a second neuron in the previous layer, Schmitt trigger mode signal 1006, output signal 1008, comparator signal 1010, first integrator signal 1012, and second integrator signal 1014.

In embodiments, the input spiking signal 1002 corresponds to, for example, the input spiking signal 614. In embodiments, the input spiking signal 1004 corresponds to, for example, the input spiking signal 616. In embodiments, the first integrator signal 1012 corresponds to the output of, for example, the first integrator circuit 602. In embodiments, the second integrator signal 1014 corresponds to the output of, for example, the second integrator circuit 604. In embodiments, the comparator signal 1010 corresponds to, for example, the output of the comparator circuit 606. In embodiments, Schmitt trigger mode signal 1006 corresponds to the output of the Schmitt trigger circuit 608 and is fed to the transistors 610, 612. In embodiments, the output signal 1008 corresponds to the output node 618, fed to the next neuron.

Input spiking signal 1004 has a higher firing rate than input spiking signal 1002 across the timing steps. As shown, input spiking signal 1002 retains approximately the same low-frequency spiking across the timing steps (e.g., 260 Hz from start to halfway and 235 Hz from halfway to end). The first integrator signal 1012 represents the input spiking signal 1002. In contrast, input spiking signal 1004 transitions from a low frequency (albeit with a higher frequency than the frequency of the input spiking signal 1002) (e.g., 320 Hz) to yet a higher frequency (e.g., 645 Hz) at the halfway point of the timing steps. The second integrator signal 1014 represents the input spiking signal 1004.

From the start until the end of the timing steps, the Schmitt trigger mode signal 1006 remains low (e.g., ‘−1’) even though the comparator signal transitions from the lower voltage to the higher voltage. As shown, the output of the comparator signal 1010 is increasing in magnitude but not polarity (e.g., from negative to positive or vice versa). This is due to the spike train of the second neuron remaining the maximally firing neuron across the period. Thus, spikes corresponding to the second neuron are propagated through to the next level.

Thus, the spike train of the maximally firing neuron (from the previous layer), in this case, the second neuron, is provided as the output signal 1008 across the timesteps (e.g., 320 Hz from start to halfway and 630 Hz from halfway to end). In this example, no spikes are missed due to transitions, apart from a short delay at the beginning during the initial integration period—the frequencies are preserved.

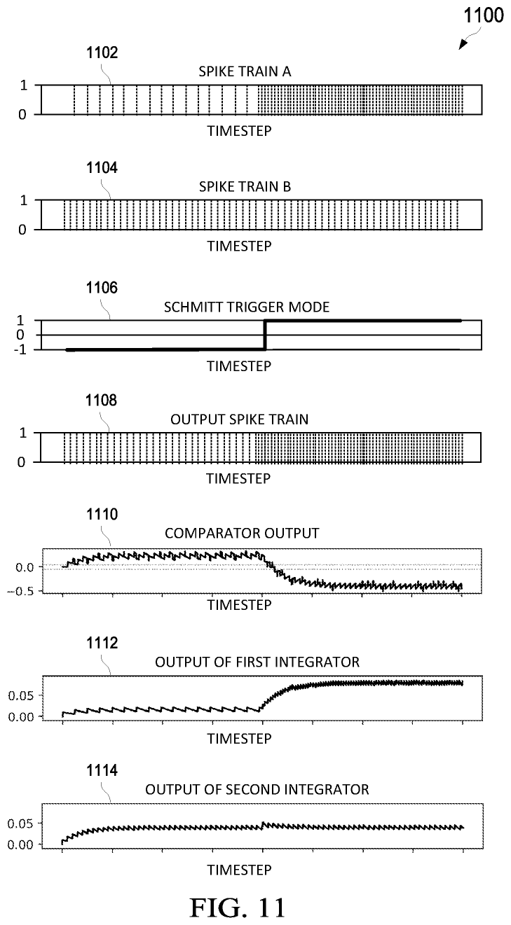

FIG. 11 illustrates signals 1100 of an embodiment operation sequence of a max-pooling neuron, as implemented in a max-pooling layer of a spiking neural network. Signals 1100 include input spiking signal 1102 from a first neuron in a previous layer, input spiking signal 1104 from a second neuron in the previous layer, Schmitt trigger mode signal 1106, output signal 1108, comparator signal 1110, first integrator signal 1112, and second integrator signal 1114.

In embodiments, the input spiking signal 1102 corresponds to, for example, the input spiking signal 614. In embodiments, the input spiking signal 1104 corresponds to, for example, the input spiking signal 616. In embodiments, the first integrator signal 1112 corresponds to the output of, for example, the first integrator circuit 602. In embodiments, the second integrator signal 1114 corresponds to the output of, for example, the second integrator circuit 604. In embodiments, the comparator signal 1110 corresponds to, for example, the output of the comparator circuit 606. In embodiments, Schmitt trigger mode signal 1106 corresponds to the output of the Schmitt trigger circuit 608 and is fed to the transistors 610, 612. In embodiments, the output signal 1108 corresponds to the output node 618, fed to the next neuron.

Input spiking signal 1102 has a higher firing rate than input spiking signal 1104 from the halfway point until the end. Input spiking signal 1104 has a higher firing rate than input spiking signal 1102 from the start until the halfway point. As shown, input spiking signal 1102 transitions from a low-frequency (e.g., 174 Hz) to a high-frequency (e.g., 808 Hz) spiking at the halfway point of the timing steps (x-axis). The first integrator signal 1112 represents the input spiking signal 1102. In contrast, input spiking signal 1104 retains approximately the same low-frequency spiking across the timing steps (e.g., 400 Hz). The second integrator signal 1114 represents the input spiking signal 1104.

At approximately the halfway point (with an additional delay), the Schmitt trigger mode signal 1106 transitions from low (e.g., ‘−1’) to high (e.g., ‘1’) as the comparator signal transitions from a higher voltage to a lower voltage.

The output signal 1108 corresponds to the input spiking signal 1104 from the second neuron until the halfway point (e.g., at a frequency of 390 Hz). After a slight delay, the output signal 1108 corresponds to the input spiking signal 1102 from the first neuron (e.g., at a frequency of 780 Hz).

Thus, the spike train of the maximally firing neuron (from the previous layer) is passed on mostly unaffected. An error may occur due to the slew rate of the filtered input, which causes a delay in the change of inputs, corresponding to the voltage drop across the transistors in the hardware implementation. The delay in the switchover can be adjusted by changing the cutoff frequency of the integrator circuits 602, 604 and the trigger point of the Schmitt trigger circuit 608.

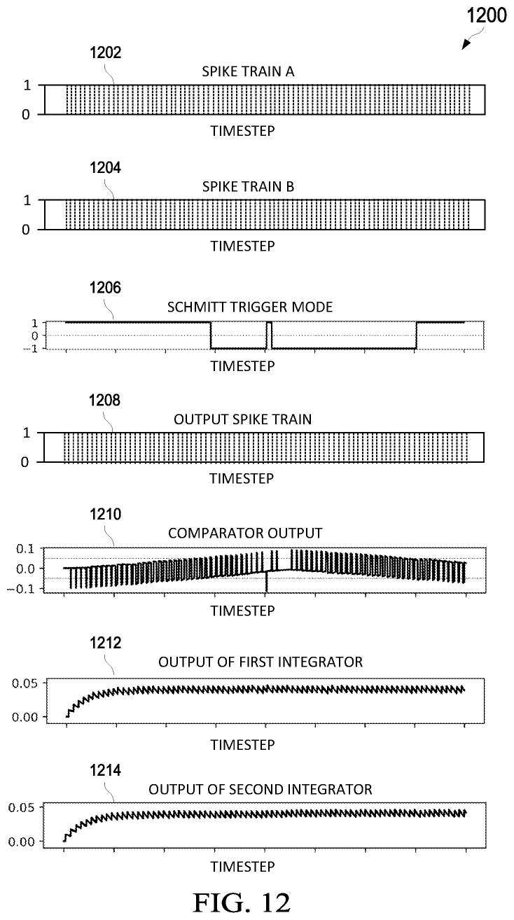

FIG. 12 illustrates signals 1200 of an embodiment operation sequence of a max-pooling neuron, as implemented in a max-pooling layer of a spiking neural network. Signals 1200 include input spiking signal 1202 from a first neuron in a previous layer, input spiking signal 1204 from a second neuron in the previous layer, Schmitt trigger mode signal 1206, output signal 1208, comparator signal 1210, first integrator signal 1212, and second integrator signal 1214.

In embodiments, the input spiking signal 1202 corresponds to, for example, the input spiking signal 614. In embodiments, the input spiking signal 1204 corresponds to, for example, the input spiking signal 616. In embodiments, the first integrator signal 1212 corresponds to the output of, for example, the first integrator circuit 602. In embodiments, the second integrator signal 1214 corresponds to the output of, for example, the second integrator circuit 604. In embodiments, the comparator signal 1210 corresponds to, for example, the output of the comparator circuit 606. In embodiments, Schmitt trigger mode signal 1206 corresponds to the output of the Schmitt trigger circuit 608 and is fed to the transistors 610, 612. In embodiments, the output signal 1208 corresponds to the output node 618, fed to the next neuron.

Input spiking signal 1202 has approximately the same firing rate as input spiking signal 1204. As shown, input spiking signal 1202 retains approximately the same frequency spiking across the timing steps (e.g., 400 Hz). The first integrator signal 1212 represents the input spiking signal 1202. Likewise, input spiking signal 1204 retains approximately the same frequency as input spiking signal 1202 (e.g., 390 Hz from start to halfway and 410 Hz from halfway to end). The second integrator signal 1214 represents the input spiking signal 1204.

The Schmitt trigger mode signal 1106 transitions between low (e.g., ‘−1’) to high (e.g., ‘1’) based on the output of the comparator signal 1210—some rapid switching between states may occur. As the Schmitt trigger mode signal 1106 transitions between low and high signals, due to the approximate spike rate of the input spiking signals 1202, 1204, max-pooling neuron 600 avoids the double-counting of the spiking, which has been an issue in previous solutions.

The output signal 1208 corresponds to the input spiking signal 1202 or input spiking signal 1204, but no double counting of the spiking exists at the output signal 1208. The rapid switching between states may be resolved by, for example, increasing the trigger level (β) of the Schmitt trigger circuit 608.

Embodiments of this disclosure improve power efficiency, reduces information loss, allow for dynamic switching, and provide greater freedom in architecture design.

A first aspect relates to a max-pooling neuron. The max-pooling neuron includes a first integrator circuit, a second integrator circuit, a comparator circuit, a Schmitt trigger circuit, and a pair of switches. The first integrator circuit is configured to filter a first input train from a first neuron of a previous layer and generate a first filtered input train. The second integrator circuit is configured to filter a second input train from a second neuron of the previous layer and generate a second filtered input train. The comparator circuit is configured to amplify a difference between the first filtered input train and the second filtered input train and generate an amplified differential signal. The Schmitt trigger circuit is configured to generate a binary output signal at an output terminal of the Schmitt trigger circuit based on the amplified differential signal. The pair of switches include a first switch and a second switch. The pair of switches have a common first terminal coupled to an output node of the max-pooling neuron and a common control terminal coupled to the output terminal of the Schmitt trigger circuit. A second terminal of the first switch is coupled to the first input train. A second terminal of the second switch is coupled to the second input train.

In a first implementation form of the max-pooling neuron according to the first aspect as such, the output node of the max-pooling neuron is coupled to the first input train in response to a spiking rate of the first input train being greater than a spiking rate of the second input train. The output node of the max-pooling neuron is coupled to the second input train in response to a spiking rate of the second input train being greater than a spiking rate of the first input train.

In a second implementation form of the max-pooling neuron according to the first aspect as such or any preceding implementation form of the first aspect, the first integrator circuit and the second integrator circuit are low-pass filter circuits. A cut-off frequency of the low-pass filter circuits is configurable to integrate the first input train and the second input train.

In a third implementation form of the max-pooling neuron according to the first aspect as such or any preceding implementation form of the first aspect, the comparator circuit includes a differential amplifier configured to provide the amplified differential signal.

In a fourth implementation form of the max-pooling neuron according to the first aspect as such or any preceding implementation form of the first aspect, the Schmitt trigger circuit includes a differential amplifier. The differential amplifier is configured to generate a first binary output signal in response to the amplified differential signal being greater than an upper threshold value and generate a second binary output signal in response to the amplified differential signal being less than a lower threshold value. The second binary output signal is different from the first binary output signal.

In a fifth implementation form of the max-pooling neuron according to the first aspect as such or any preceding implementation form of the first aspect, trigger levels of the Schmitt trigger circuit are adjustable to set the upper threshold value and the lower threshold value.

In a sixth implementation form of the max-pooling neuron according to the first aspect as such or any preceding implementation form of the first aspect, the first switch is a p-type metal-oxide-semiconductor field-effect transistor (MOSFET), the second switch is an n-type MOSFET, and the first switch and the second switch are arranged as a complementary MOSFET (CMOS).

A second aspect relates to a max-pooling layer with a max-pooling neuron. The max-pooling neuron includes a first integrator circuit, a second integrator circuit, a comparator circuit, a Schmitt trigger circuit, and a pair of switches. The first integrator circuit is configured to filter a first input train from a first neuron of a previous layer and generate a first filtered input train. The second integrator circuit is configured to filter a second input train from a second neuron of the previous layer and generate a second filtered input train. The comparator circuit is configured to amplify a difference between the first filtered input train and the second filtered input train and generate an amplified differential signal. The Schmitt trigger circuit is configured to generate a binary output signal at an output terminal of the Schmitt trigger circuit based on the amplified differential signal. The pair of switches include a first switch and a second switch. The pair of switches have a common first terminal coupled to an output node of the max-pooling neuron and a common control terminal coupled to the output terminal of the Schmitt trigger circuit. A second terminal of the first switch is coupled to the first input train. A second terminal of the second switch is coupled to the second input train.

In a first implementation form of the max-pooling layer according to the second aspect as such, the output node of the max-pooling neuron is coupled to the first input train in response to a spiking rate of the first input train being greater than a spiking rate of the second input train. The output node of the max-pooling neuron is coupled to the second input train in response to a spiking rate of the second input train being greater than a spiking rate of the first input train.

In a second implementation form of the max-pooling layer according to the second aspect as such or any preceding implementation form of the second aspect, the first integrator circuit and the second integrator circuit are low-pass filter circuits. A cut-off frequency of the low-pass filter circuits is configurable to integrate the first input train and the second input train.

In a third implementation form of the max-pooling layer according to the second aspect as such or any preceding implementation form of the second aspect. The comparator circuit includes a differential amplifier configured to provide the amplified differential signal.

In a fourth implementation form of the max-pooling layer according to the second aspect as such or any preceding implementation form of the second aspect, the Schmitt trigger circuit includes a differential amplifier. The differential amplifier is configured to generate a first binary output signal in response to the amplified differential signal being greater than an upper threshold value and generate a second binary output signal in response to the amplified differential signal being less than a lower threshold value. The second binary output signal is different from the first binary output signal.

In a fifth implementation form of the max-pooling layer according to the second aspect as such or any preceding implementation form of the second aspect, trigger levels of the Schmitt trigger circuit are adjustable to set the upper threshold value and the lower threshold value.

In a sixth implementation form of the max-pooling layer according to the second aspect as such or any preceding implementation form of the second aspect, the first switch is a p-type metal-oxide-semiconductor field-effect transistor (MOSFET), the second switch is an n-type MOSFET, and the first switch and the second switch are arranged as a complementary MOSFET (CMOS).

A third aspect relates to a neural network. The neural network includes a first layer and a max-pooling layer. The first layer includes a first neuron and a second neuron. The first neuron is configured to provide a first input train. The second neuron is configured to provide a second input train. The max-pooling layer includes a max-pooling neuron. The max-pooling neuron includes a first integrator circuit, a second integrator circuit, a comparator circuit, a Schmitt trigger circuit, and a pair of switches. The first integrator circuit is configured to filter a first input train from a first neuron of a previous layer and generate a first filtered input train. The second integrator circuit is configured to filter a second input train from a second neuron of the previous layer and generate a second filtered input train. The comparator circuit is configured to amplify a difference between the first filtered input train and the second filtered input train and generate an amplified differential signal. The Schmitt trigger circuit is configured to generate a binary output signal at an output terminal of the Schmitt trigger circuit based on the amplified differential signal. The pair of switches include a first switch and a second switch. The pair of switches have a common first terminal coupled to an output node of the max-pooling neuron and a common control terminal coupled to the output terminal of the Schmitt trigger circuit. A second terminal of the first switch is coupled to the first input train. A second terminal of the second switch is coupled to the second input train.

In a first implementation form of the neural network according to the third aspect as such, the first layer is a convolutional layer.

In a second implementation form of the neural network according to the third aspect as such or any preceding implementation form of the third aspect, the neural network is a spiking neural network (SNN).

In a third implementation form of the neural network according to the third aspect as such or any preceding implementation form of the third aspect, the first integrator circuit and the second integrator circuit are low-pass filter circuits. A cut-off frequency of the low-pass filter circuits is configurable to integrate the first input train and the second input train. The comparator circuit includes a differential amplifier configured to provide the amplified differential signal.

In a fourth implementation form of the neural network according to the third aspect as such or any preceding implementation form of the third aspect, the Schmitt trigger circuit includes a differential amplifier. The differential amplifier is configured to generate a first binary output signal in response to the amplified differential signal being greater than an upper threshold value and generate a second binary output signal in response to the amplified differential signal being less than a lower threshold value. The second binary output signal is different from the first binary output signal. The trigger levels of the Schmitt trigger circuit are adjustable to set the upper threshold value and the lower threshold value.

In a fifth implementation form of the neural network according to the third aspect as such or any preceding implementation form of the third aspect, the first switch is a p-type metal-oxide-semiconductor field-effect transistor (MOSFET), the second switch is an n-type MOSFET, and the first switch and the second switch are arranged as a complementary MOSFET (CMOS).

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

The specification and drawings are, accordingly, to be regarded simply as an illustration of the disclosure as defined by the appended claims, and are contemplated to cover any and all modifications, variations, combinations, or equivalents that fall within the scope of the present disclosure.

What is claimed is:

1. A max-pooling neuron, comprising:
a first integrator circuit configured to filter a first input train from a first neuron of a previous layer and generate a first filtered input train;
a second integrator circuit configured to filter a second input train from a second neuron of the previous layer and generate a second filtered input train;
a comparator circuit configured to amplify a difference between the first filtered input train and the second filtered input train and generate an amplified differential signal;
a Schmitt trigger circuit configured to generate a binary output signal at an output terminal of the Schmitt trigger circuit based on the amplified differential signal; and
a pair of switches comprising a first switch and a second switch, the pair of switches having a common first terminal coupled to an output node of the max-pooling neuron, the pair of switches having a common control terminal coupled to the output terminal of the Schmitt trigger circuit, a second terminal of the first switch coupled to the first input train, and a second terminal of the second switch coupled to the second input train.

2. The max-pooling neuron of claim 1, wherein the output node of the max-pooling neuron is coupled to the first input train in response to a spiking rate of the first input train being greater than a spiking rate of the second input train, and wherein the output node of the max-pooling neuron is coupled to the second input train in response to a spiking rate of the second input train being greater than a spiking rate of the first input train.

3. The max-pooling neuron of claim 1, wherein the first integrator circuit and the second integrator circuit are low-pass filter circuits, and wherein a cut-off frequency of the low-pass filter circuits is configurable to integrate the first input train and the second input train.

4. The max-pooling neuron of claim 1, wherein the comparator circuit comprises a differential amplifier configured to provide the amplified differential signal.

5. The max-pooling neuron of claim 1, wherein the Schmitt trigger circuit comprises a differential amplifier, the differential amplifier configured to:
generate a first binary output signal in response to the amplified differential signal being greater than an upper threshold value; and
generate a second binary output signal in response to the amplified differential signal being less than a lower threshold value, the second binary output signal being different from the first binary output signal.

6. The max-pooling neuron of claim 5, wherein trigger levels of the Schmitt trigger circuit are adjustable to set the upper threshold value and the lower threshold value.

7. The max-pooling neuron of claim 1, wherein the first switch is a p-type metal-oxide-semiconductor field-effect transistor (MOSFET), wherein the second switch is an n-type MOSFET, and wherein the first switch and the second switch are arranged as a complementary MOSFET (CMOS).

8. A max-pooling layer comprising a max-pooling neuron, the max-pooling layer comprising:
a first integrator circuit configured to filter a first input train from a first neuron of a previous layer and generate a first filtered input train;
a second integrator circuit configured to filter a second input train from a second neuron of the previous layer and generate a second filtered input train;
a comparator circuit configured to amplify a difference between the first filtered input train and the second filtered input train and generate an amplified differential signal;
a Schmitt trigger circuit configured to generate a binary output signal based on the amplified differential signal; and
a pair of switches comprising a first switch and a second switch, the pair of switches having a common first terminal coupled to an output node of the max-pooling neuron, the pair of switches having a common control terminal configured to receive the binary output signal of the Schmitt trigger circuit, a second terminal of the first switch coupled to the first input train, and a second terminal of the second switch coupled to the second input train.

9. The max-pooling layer of claim 8, wherein the output node of the max-pooling neuron is coupled to the first input train in response to a spiking rate of the first input train being greater than a spiking rate of the second input train, and wherein the output node of the max-pooling neuron is coupled to the second input train in response to a spiking rate of the second input train being greater than a spiking rate of the first input train.

10. The max-pooling layer of claim 8, wherein the first integrator circuit and the second integrator circuit are low-pass filter circuits, and wherein a cut-off frequency of the low-pass filter circuits is configurable to integrate the first input train and the second input train.

11. The max-pooling layer of claim 8, wherein the comparator circuit comprises a differential amplifier configured to provide the amplified differential signal.

12. The max-pooling layer of claim 8, wherein the Schmitt trigger circuit comprises a differential amplifier, the differential amplifier configured to:
generate a first binary output signal in response to the amplified differential signal being greater than an upper threshold value; and
generate a second binary output signal in response to the amplified differential signal being less than a lower threshold value, the second binary output signal being different from the first binary output signal.

13. The max-pooling layer of claim 12, wherein trigger levels of the Schmitt trigger circuit are adjustable to set the upper threshold value and the lower threshold value.

14. The max-pooling layer of claim 8, wherein the first switch is a p-type metal-oxide-semiconductor field-effect transistor (MOSFET), wherein the second switch is an n-type MOSFET, and wherein the first switch and the second switch are arranged as a complementary MOSFET (CMOS).

15. A neural network, comprising:
a first layer having a first neuron and a second neuron, the first neuron configured to provide a first input train, the second neuron configured to provide a second input train; and
a max-pooling layer having a max-pooling neuron, the max-pooling neuron comprising:
a first integrator circuit configured to filter the first input train and generate a first filtered input train,
a second integrator circuit configured to filter the second input train and generate a second filtered input train,
a comparator circuit configured to amplify a difference between the first filtered input train and the second filtered input train and generate an amplified differential signal,
a Schmitt trigger circuit configured to generate a binary output signal based on the amplified differential signal, and
a pair of switches comprising a first switch and a second switch, the pair of switches having a common first terminal coupled to an output node of the max-pooling neuron, the pair of switches having a common control terminal configured to receive the binary output signal of the Schmitt trigger circuit, a second terminal of the first switch coupled to the first input train, and a second terminal of the second switch coupled to the second input train.

16. The neural network of claim 15, wherein the first layer is a convolutional layer.

17. The neural network of claim 15, wherein the neural network is a spiking neural network (SNN).

18. The neural network of claim 15, wherein the first integrator circuit and the second integrator circuit are low-pass filter circuits, wherein a cut-off frequency of the low-pass filter circuits is configurable to integrate the first input train and the second input train, and wherein the comparator circuit comprises a differential amplifier configured to provide the amplified differential signal.

19. The neural network of claim 15, wherein the Schmitt trigger circuit comprises a differential amplifier, the differential amplifier configured to:
generate a first binary output signal in response to the amplified differential signal being greater than an upper threshold value; and
generate a second binary output signal in response to the amplified differential signal being less than a lower threshold value, the second binary output signal being different from the first binary output signal, wherein trigger levels of the Schmitt trigger circuit are adjustable to set the upper threshold value and the lower threshold value.

20. The neural network of claim 15, wherein the first switch is a p-type metal-oxide-semiconductor field-effect transistor (MOSFET), wherein the second switch is an n-type MOSFET, and wherein the first switch and the second switch are arranged as a complementary MOSFET (CMOS).
